(19) United States
(12) Patent Application Publication
(10) Pub. No.: US 2020/0236618 A1
(43) Pub. Date: Jul. 23, 2020

(54) METHOD AND APPARATUS FOR GUARANTEEING STABILITY AND PERFORMANCE OF WIRELESS COMMUNICATION

(71) Applicant: SAMSUNG ELECTRONICS CO., LTD., SUWON-SI (KR)

(72) Inventors: HYUNSEOK YU, SUWON-SI (KR); JUNSE LEE, SUWON-SI (KR)

(21) Appl. No.: 16/694,718

(22) Filed: Nov. 25, 2019

(30) Foreign Application Priority Data
Jan. 18, 2019 (KR) 10-2019-0006948
May 28, 2019 (KR) 10-2019-0062582

(51) Int. Cl. H04W 52/02; H04B 1/3827; H04W 52/28; H04B 17/309; H04W 52/36; H03F 1/30; H03F 3/68; G06N 3/08; G06N 3/04

(52) U.S. Cl. CPC H04W 52/028; H04B 1/3838; H04W 52/28; H04B 17/309; H04W 52/36; H03F 2200/447; H03F 3/68; G06N 3/08; G06N 3/04; H03F 2200/451; H03F 2200/294; H03F 1/30

(57) ABSTRACT

A wireless communication device includes multiple radio frequency (RF) modules, a back-end module, and a controller. The RF modules are each connected to at least one antenna and each include a temperature sensor. The back-end module is configured to generate a baseband signal from signals provided by the RF modules. The controller is configured to switch RF modules based on temperatures of the RF modules so that wireless communication performed by a first RF module among the RF modules is performed by a second RF module among the RF modules.

### CROSS-REFERENCE TO RELATED APPLICATIONS

This application claims the benefit of priority under 35 U.S.C. § 119 to Korean Patent Application No. 10-2019-0006948, filed on Jan. 18, 2019 in the Korean Intellectual Property Office, and to Korean Patent Application No. 10-2019-0062582, filed on May 28, 2019 in the Korean Intellectual Property Office, the disclosures of which are incorporated herein in their entirety by reference.

### BACKGROUND

### 1. Technical Field

The present disclosure relates to wireless communication. More particularly, the present disclosure relates to a method and apparatus for guaranteeing stability and performance of the wireless communication.

### 2. Description of the Related Art

In a wireless communication system, since signal transmission may be easily affected by path loss and shadow fading, sufficient power may be required so that quality of service (QoS) does not deteriorate. In particular, a signal having a high frequency band such as the mmWave frequency band may be easily attenuated. High transmission power may be required for such a signal having a high frequency band that may be easily attenuated. However, as a wireless communication device increases transmission power, heat emission may increase in the wireless communication device. Additionally, as the number of antennas for beamforming and polarization increases in the wireless communication device, power consumption and heat emission may increase. The wireless communication and a wireless communication device such as a portable user terminal used for transmitting in the wireless communication may be required to have high performance and to maintain stability.

### SUMMARY

The present disclosure describes a method and apparatus for maintaining stability and performance of wireless communication by managing heat emission while maintaining quality of the wireless communication.

According to an aspect of the present disclosure, a wireless communication device includes a plurality of radio frequency (RF) modules, a back-end module, and a controller. The RF modules are each connected to at least one antenna and each include a temperature sensor. The back-end module is configured to generate a baseband signal from signals provided by the plurality of RF modules. The controller is configured to switch RF modules based on temperatures of the plurality of RF modules so that a RF module performing wireless communication among the plurality of RF modules is changed from a first RF module to a second RF module.

According to another aspect of the present disclosure, a method for guaranteeing stability and performance of wireless communication using a plurality of RF modules includes determining whether to switch the RF modules based on a temperature of a first RF module performing the wireless communication among the plurality of RF modules. The method also includes selecting a second RF module among the plurality of RF modules based on temperatures of the plurality of RF modules based on determining to switch the RF modules and controlling the second RF module to perform the wireless communication.

According to another aspect of the present disclosure, a wireless communication device includes a plurality of RF modules each connected to at least one antenna and each including a temperature sensor and a state machine configured to transit among a plurality of states based on temperatures of the plurality of RF modules and quality of wireless communication provided by each of the plurality of RF modules. The plurality of states may include a first state in which a first RF module among the plurality of RF modules performs wireless communication at a temperature lower than or equal to a first threshold value, a second state in which the first RF module performs the wireless communication at a temperature higher than the first threshold value, a third state in which switching RF modules is performed so that a second RF module among the plurality of RF modules performs the wireless communication, and a fourth state in which the plurality of RF modules are set to be in a sleep mode.

### BRIEF DESCRIPTION OF THE DRAWINGS

Embodiments of the present disclosure will be more clearly understood from the following detailed description taken in conjunction with the accompanying drawings in which:

FIG. 1 is a block diagram illustrating a wireless communication system including a wireless communication device, according to an exemplary embodiment of the present disclosure;

FIG. 2 is a flowchart illustrating a method of guaranteeing stability and performance of wireless communication, according to an exemplary embodiment of the present disclosure;

FIG. 3 is a block diagram illustrating an example of a radio frequency (RF) module, according to an exemplary embodiment of the present disclosure;

FIG. 4 is a graph illustrating an example of switching RF modules according, to an exemplary embodiment of the present disclosure;

FIG. 5 is a flowchart illustrating another method of guaranteeing stability and performance of wireless communication, according to an exemplary embodiment of the present disclosure;

FIG. 6 is a block diagram illustrating another example of an RF module, according to an exemplary embodiment of the present disclosure;

FIG. 7 is a block diagram illustrating an example of a back-end module, according to an exemplary embodiment of the present disclosure;

FIG. 8 is a flowchart illustrating another method of guaranteeing stability and performance of wireless communication, according to an exemplary embodiment of the present disclosure;

FIG. 9 is a flowchart illustrating another method of guaranteeing stability and performance of wireless communication, according to an exemplary embodiment of the present disclosure;

FIG. 10 is a flowchart illustrating another method of guaranteeing stability and performance of wireless communication, according to an exemplary embodiment of the present disclosure;

FIG. 11A illustrates a table used in an operation of limiting transmission power of an RF module, according to exemplary embodiments of the present disclosure;

FIG. 11B illustrates an operation of an artificial neural network in limiting transmission power of an RF module, according to exemplary embodiments of the present disclosure;

FIG. 12 is a flowchart illustrating another method of guaranteeing stability and performance of wireless communication, according to an exemplary embodiment of the present disclosure;

FIG. 13 illustrates a test machine for performing a method of guaranteeing stability and performance of wireless communication, according to an exemplary embodiment of the present disclosure; and

FIG. 14 is a block diagram illustrating an example of a communication device, according to an exemplary embodiment of the present disclosure.

### DETAILED DESCRIPTION OF THE EMBODIMENTS

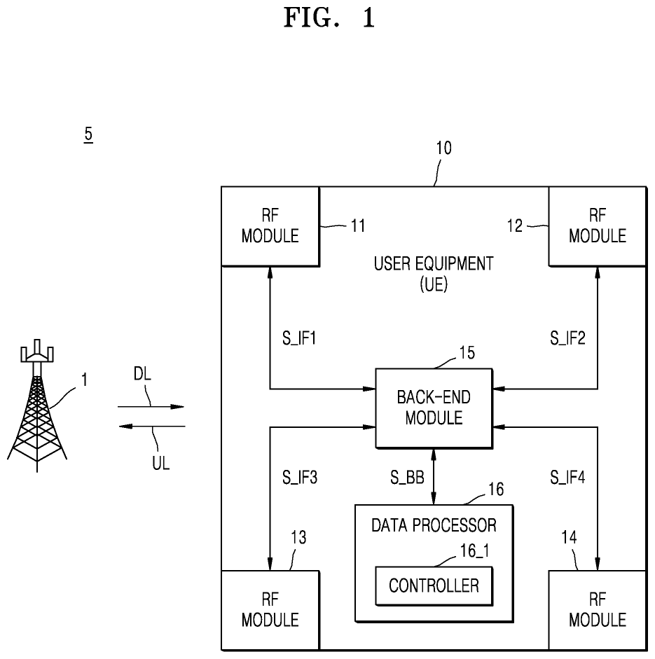

FIG. 1 is a block diagram illustrating a wireless communication system 5 including a wireless communication device, according to an exemplary embodiment of the present disclosure. As a non-restrictive example, the wireless communication system 5 may be a wireless communication system using a cellular network such as a 5th generation wireless (5G) system, a long term evolution (LTE) system, an LTE-Advanced system, a code division multiple access (CDMA) system, or a global system for mobile communications (GSM) system. Alternatively, the wireless communication system 5 may also be, for example, a wireless local area network (WLAN) system, or another arbitrary wireless communication system. Hereinafter, the wireless communication system 5 will be mainly described with reference to the wireless communication system using a cellular network. However, it will be understood that the exemplary embodiments of the present disclosure are not limited thereto.

A BS 1 (base station) may commonly refer to a fixed station that communicates over the air (OTA), i.e., wirelessly, with a user device and/or with another BS. The BS 1 may also communicate with another BS over a wired connection such as a broadband connection. The BS 1 may switch data and control information by communicating with the user device and/or the other BS. For example, the BS 1 may be a base station transceiver (BTS) in CDMA, a node-B of WCDMA, an evolved-node B (eNB) in LTE, a next generation node B (gNB) of 5G, a sector hub, a cell site, a base transceiver system (BTS), an access point (AP), a relay node, a remote radio head (RRH), a radio unit (RU), or a small cell. In the current specification, a cell may be understood as a partial region covered by an individual base station transceiver (BTS) or by a base station controller (BSC) that controls one or more base station transceivers in CDMA, covered by a node-B of WCDMA, covered by an eNB in LTE, or covered by a gNB of 5G. Also or alternatively, a cell may be understood as a sector and may cover various coverage regions such as mega-cell, macro-cell, microcell, pico-cell, pemto-cell, relay node, RRH, RU, and small cell communication ranges.

UE 10 (user equipment) may refer to fixed or mobile arbitrary devices that may transmit and receive the data and/or the control information by communicating with a BS, for example, the BS 1. For example, the UE 10 may be referred to as a terminal, terminal equipment, a mobile station (MS), a mobile terminal (MT), a user terminal (UT), a subscriber station (SS), a wireless device, or a handheld device. Hereinafter, the exemplary embodiments of the present disclosure will be described with reference to the UE 10 as the wireless communication device. However, it will be understood that the exemplary embodiments of the present disclosure are not limited thereto.

A wireless communication network between the UE 10 and the BS 1 may support multiple users to communicate with each other by sharing available network resources. For example, in the wireless communication network, information may be transmitted by various multiple access methods such as code division multiple access (CDMA), frequency division multiple access (FDMA), time division multiple access (TDMA), an orthogonal frequency division multiple access (OFDMA), single carrier frequency division multiple access (SC-FDMA), OFDM-FDMA, OFDM-TDMA, and OFDM-CDMA. As illustrated in FIG. 1, the UE 10 may communicate with the BS 1 through an uplink UL and a downlink DL. In some embodiments, like in a device-to-device (D2D) communication or mode, user equipment components may communicate with each other through a sidelink.

The UE 10 may support accesses to two or more wireless communication systems. For example, the UE 10 may access a first wireless communication system and a second wireless communication system that are different from each other. For example, the first wireless communication system may use a higher frequency band than the second wireless communication system. The first wireless communication system may be a wireless communication system (for example, 5G) that uses mmWave, and the second wireless communication system may be a wireless communication system (for example, LTE) using a lower frequency band than mmWave and may be referred to as a legacy wireless communication system. The UE 10 may respectively access the first wireless communication system and the second wireless communication system through different BSs in some embodiments or may respectively access the first wireless communication system and the second wireless communication system through the BS 1 in some embodiments. In addition, in some embodiments, the UE 10 may support accesses to three or more different wireless communication systems. As illustrated in FIG. 1, the UE 10 may include first RF module 11 to fourth RF module 14, a back-end module 15, and a data processor 16. In some embodiments, the first RF module 11 to the fourth RF module 14 may be respectively included in independent semiconductor packages. In some embodiments, the back-end module 15 and the data processor 16 may be included in one semiconductor package or may be respectively included in independent semiconductor packages.

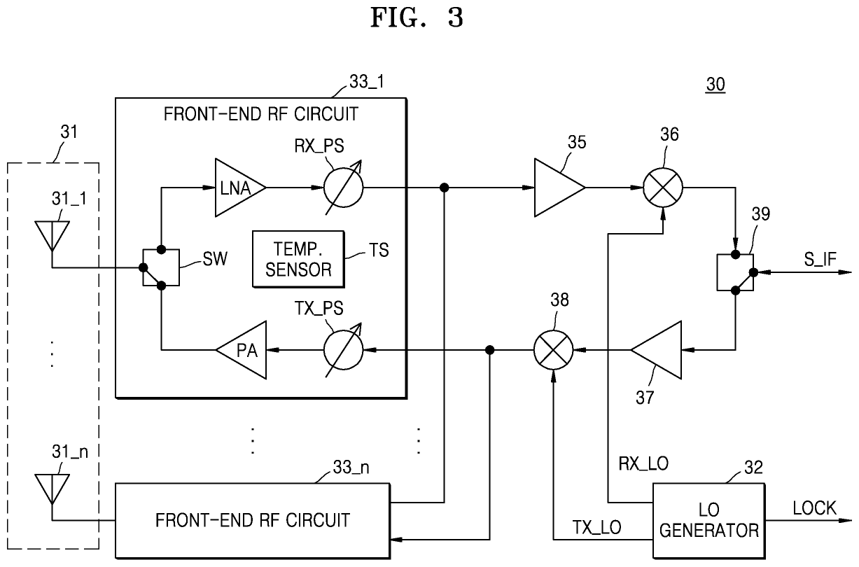

Each of the first RF module 11 to the fourth RF module 14 may include or be directly or indirectly connected to at least one antenna and may process a signal received through the antenna(s) and a signal transmitted through the antenna(s). In some embodiments, the first RF module 11 to the fourth RF module 14 may generate or process first IF signal S_IF1 (intermediate frequency signals S_IF1) to fourth IF signal S_IF4 (intermediate frequency signal S_IF4). For example, the first RF module 11 may generate the first IF signal S_IF1 from a radio frequency (RF) signal received through the antenna by down-converting the received RF signal to the first IF signal S_IF1. The first RF module 11 may output an RF signal through the antenna by up-converting the first IF signal S_IF1 to generate the RF signal. In some embodiments, each of the first RF module 11 to the fourth RF module 14 may include an antenna array, a front-end RF circuit, a buffer, and a switch as described later with reference to FIG. 3. In some embodiments, the UE 10 may include the first RF module 11 to the fourth RF module 14 in order to access the first wireless communication system using the high frequency band and may further include an additional RF module in order to access the second wireless communication system using a low frequency band. In the current specification, the first RF module 11 to the fourth RF module 14 may be referred to as front-end modules or RF modules.

In the high frequency band such as mmWave, a signal with a short wavelength may have high straightness. Therefore, communication quality may be influenced by interruption by obstacles and/or a direction of an antenna. The UE 10 may include multiple antenna modules, for example, the first RF module 11 to the fourth RF module 14, so that it is possible to communicate with the BS 1 although transmission and reception of a signal through some antenna modules are blocked by an obstacle such as the body of a user or in spite of a direction of the UE 10. As illustrated in FIG. 1, the first RF module 11 to the fourth RF module 14 included in the UE 10 may be apart from each other. In some embodiments, the first RF module 11 to the fourth RF module 14 may be apart from each other at an edge of the UE 10. In some embodiments, unlike in FIG. 1, the UE 10 may include less or more than four front end RF modules.

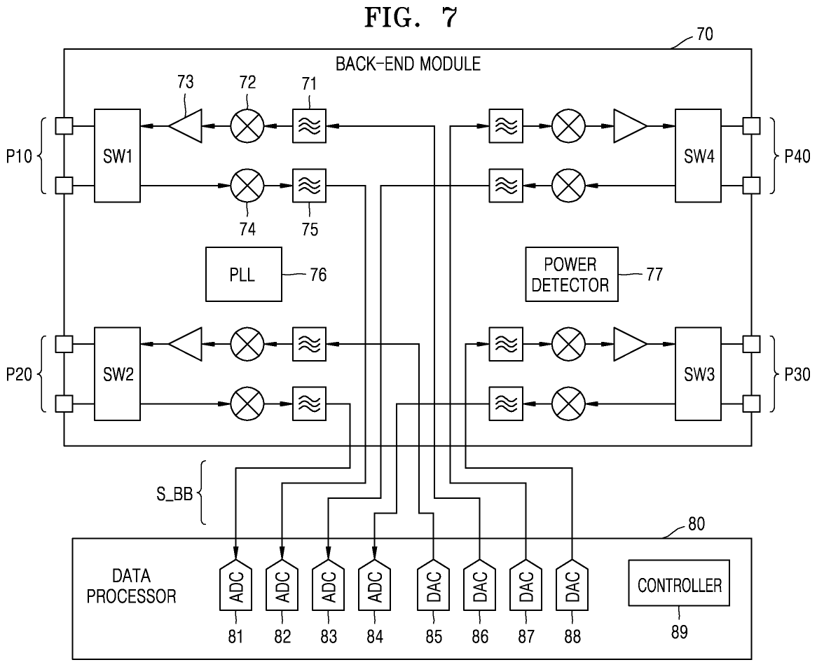

The back-end module 15 may generate a baseband signal S_BB by down converting the intermediate frequency (IF) signals S_IF1 from the first RF module 11, S_IF2 from the second RF module 12, S_IF3 from the third RF module 13, and S_IF4 from the fourth RF module 14. For example, the back-end module 15 may generate at least one of the first IF signal S_IF1 to the fourth IF signal S_IF4 by processing the baseband signal S_BB provided from the data processor 16 and may generate the baseband signal S_BB by processing at least one of the first IF signal IF signal S_IF1 to the fourth IF signal S_IF4. In some embodiments, the first RF module 11 to the fourth RF module 14 may respectively perform down conversion to generate baseband signals and provide the generated baseband signals to the data processor 16 directly or indirectly via the back-end module 15. In this case, the back-end module 15 processes the baseband signal S_BB without having to generate the baseband signal S_BB, since down conversion and up conversion are performed by the first RF module 11 to the fourth RF module 14 and down conversion and up conversion do not have to be performed by the back-end module 15. A detailed example of the back-end module 15 will be described later with reference to FIG. 7.

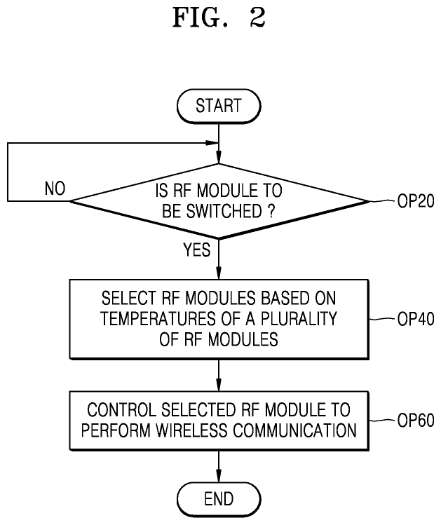

The data processor 16 may extract information transmitted from the BS 1 from the baseband signal S_BB received from the back-end module 15. The data processor 16 may also generate the baseband signal S_BB including information to be transmitted to the BS 1. As illustrated in FIG. 1, the data processor 16 may include a controller 16_1. The controller 16_1 may obtain temperatures of the first RF module 11 to the fourth RF module 14 and may determine at least one RF module used for wireless communication with the BS 1. For example, the controller 16_1 may switch the current RF module used for the wireless communication to another RF module based on the temperatures of one or more of the first RF module 11 to the fourth RF module 14. Of course, the switching of RF modules may be based on a single temperature of a single RF module, such as an RF module currently or most recently being used for transmission in the wireless communication. Therefore, it is possible to prevent the RF module(s) from being overheated and to maintain the wireless communication with the BS 1. The controller 16_1 may be logic hardware designed through logic synthesis, a processing unit including a software module including a series of commands and a processor for executing the series of commands, or a combination of the logic hardware and the processing unit. An example of an operation of the controller 16_1 will be described with reference to FIG. 2.

FIG. 2 is a flowchart illustrating a method for guaranteeing stability and performance of wireless communication, according to an exemplary embodiment of the present disclosure. As illustrated in FIG. 2, the method for guaranteeing the stability and performance of the wireless communication may include multiple operations OP20, OP40, and OP60. In some embodiments, the method of FIG. 2 may be performed by the controller 16_1 of FIG. 1.

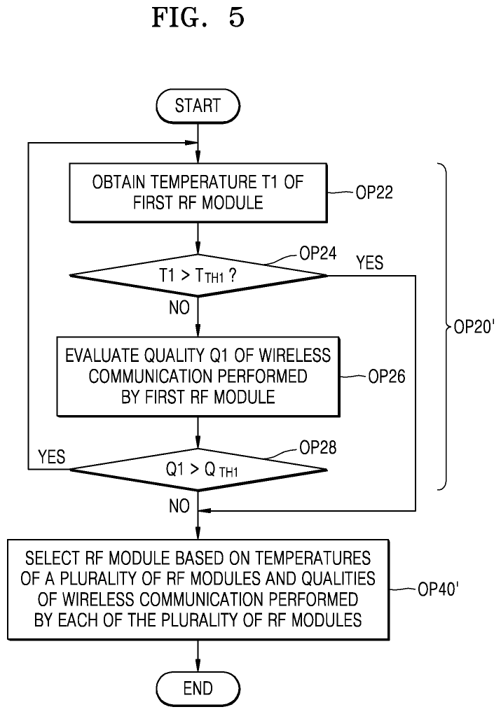

In operation OP20, an operation of determining whether the RF module is to be switched may be performed. For example, the controller 16_1 may determine whether the RF module is to be switched based on the temperatures of one or more of the first RF module 11 to the fourth RF module 14. Herein, switching RF modules may denote allowing an RF module, which is different from an RF module currently performing the wireless communication, to perform the wireless communication. Switching RF modules may involve direct or indirect control such as by providing a digital or analog instruction or signal. For example, when the first RF module 11 currently performs the wireless communication with the BS 1, the controller 16_1 may determine whether an RF module different from the first RF module 11, that is, one of the second RF module 12 to fourth RF module 14, should be used to perform the wireless communication. In some embodiments, when the temperature of the first RF module 11 that performs the wireless communication exceeds a previously defined threshold value, the controller 16_1 may determine that the first RF module 11 is to be switched out (e.g., partially or fully inactivated or deactivated, or turned off, or disconnected) in order to prevent the first RF module 11 from being overheated. For example, power supplied to some or all of the elements in the first RF module 11 may be blocked when the first RF module 11 is switched out and replaced with another of the second RF module 12 to the fourth RF module 14. Individual elements of the first RF module 11 may be inactivated or deactivated, or disconnected, or switched off for example when the first RF module 11 is switched out and replaced for communication by another of the second RF module 12 to the fourth RF module 14. As illustrated in FIG. 2, operation OP40 may be subsequently performed when it is determined that an RF module is to be switched, and operation OP20 may be performed again when it is determined that the first RF module 11 is not to be switched. Hereinafter, it is assumed that the first RF module 11 currently performs the wireless communication and an example of operation OP20 will be described later with reference to FIG. 5.

In operation OP40, an operation of selecting an RF module based on the temperatures of one or more of the first RF module 11 to the fourth RF module 14 may be performed. For example, the controller 16_1 may select the RF module based on the temperatures of one or more of the first RF module 11 to the fourth RF module 14 including the first RF module 11 that currently performs the wireless communication. In some embodiments, the controller 16_1 may select the first RF module 11 or an RF module different from the first RF module 11, for example, one of the second RF module 12 to the fourth RF module 14 based on the temperatures of the first RF module 11 to the fourth RF module 14. For example, the controller 16_1 may select the RF module having the lowest temperature among the first RF module 11 to the fourth RF module 14. In addition, as described later with reference to FIG. 5, the controller 16_1 may select the RF module based on qualities of the wireless communication respectively provided by the first RF module 11 to fourth RF module 14 as well as the temperatures of one or more of the first RF module 11 to the fourth RF module 14.

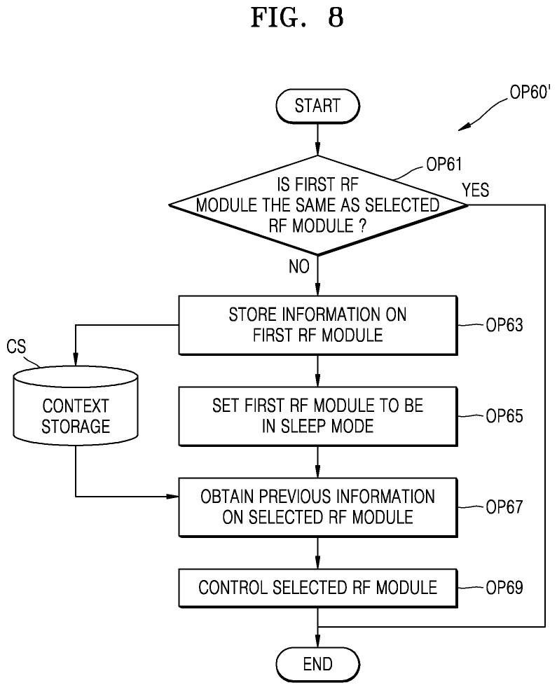

In operation OP60, an operation of controlling the selected RF module to perform the wireless communication may be performed. For example, in operation OP40, the second RF module 12 may be selected and the controller 16_1 may set the second RF module 12 so that the second RF module 12 performs the wireless communication and may control a switch so that a path for generating or processing the second IF signal S_IF2 is formed. In addition, in operation OP40, when the RF module different from the first RF module 11 is selected, the controller 16_1 may set the first RF module 11 in a sleep mode such as by partially or fully inactivating or deactivating or turning off and/or disconnecting the first RF module 11. For example, individual elements (components) of the first RF module 11 may be inactivated or deactivated, or disconnected, or switched off for example when the first RF module 11 is switched out and replaced for communication by another of the second RF module 12 to the fourth RF module 14. Therefore, the temperature of the first RF module 11 may be reduced and the selected RF module may subsequently perform the wireless communication. An example of operation OP60 will be described later with reference to FIG. 8.

FIG. 3 is a block diagram illustrating an example of an RF module 30, according to an exemplary embodiment of the present disclosure. In detail, the RF module 30 of FIG. 3 may be an example of the first RF module 11 to the fourth RF module 14. As described above with reference to FIG. 1, the RF module 30 may generate the IF signal S_IF by processing an RF signal received through an antenna array 31 and may generate and output an RF signal through the antenna array 31 by processing the IF signal S_IF. As illustrated in FIG. 3, the RF module 30 may include the antenna array 31, a LO generator 32 (local oscillation generator), multiple front-end RF circuits 33_1 to 33_n, buffers 35 and 37, RX mixer 36 and TX mixer 38, and a switch 39 (n is an integer greater than 1). Hereinafter, FIG. 3 will be described in the context of and with reference to FIG. 1.

The antenna array 31 may include multiple antennas 31_1 to 31_n. the antennas 31_1 to 31_n may be used for beamforming as described above with reference to FIG. 1 and for transmitting and receiving signals polarized in different directions. As illustrated in FIG. 3, the RF module 30 may include the front-end RF circuits 33_1 to 33_n respectively corresponding to the antennas 31_1 to 31_n. Therefore, power consumed by the front-end RF circuits 33_1 to 33_n in order to drive the antennas 31_1 to 31_n may increase.

The front-end RF circuit 33_1 may include a switch SW, a low noise amplifier LNA, an RX phase shifter RX_PS, a TX phase shifter TX_PS, a power amplifier PA, and a temperature sensor TS. The temperature sensor TS may sense a temperature of the front-end RF circuit 33_1. For example, the front-end RF circuits 33_1 to 33_n may respectively include temperature sensors and the temperature sensors may provide a signal including information on sensed temperatures to the controller 16_1 of FIG. 1. In some embodiments, the RF module 30 may further include an element for collecting signals provided by one or more of the temperature sensors of the front-end RF circuits 33_1 to 33_n and providing a signal including temperature information (for example, an average of temperatures and a maximum value) to the controller 16_1 based on the collected signals.

The LO generator 32 may provide LO signals to the RX mixer 36 and the TX mixer 38. For example, the LO generator 32 may provide a TX_LO signal TX_LO having a frequency determined based on a carrier frequency used for transmission to the TX mixer 38. Additionally, the LO generator 32 may provide an RX_LO signal RX_LO having a frequency determined based on a carrier frequency used for reception to the RX mixer 36. In some embodiments, the LO generator 32 may include a phase locked loop (PLL) and may output a lock signal LOCK representing that the TX_LO signal TX_LO and/or the RX_LO signal RX_LO reaches a desired frequency. The lock signal LOCK may be provided to the controller 16_1 and the controller 16_1 may determine whether the RF module 30 may normally operate based on the activated lock signal LOCK. In some embodiments, the buffers 35 and 37 and the RX mixer 36 and TX mixer 38 may be arranged in a different way from FIG. 3. In addition, in some embodiments, the RX mixer 36, the TX mixer 38 and the LO generator 32 may be omitted. When the RX mixer 36, the TX mixer 38 and the LO generator 32 are omitted, the RF module 30 may receive a signal of an RF band from the back-end module 15 or may provide the signal of the RF band to the back-end module 15.

The RF module 30 may be set to be in the sleep mode by the controller 16_1 and may stop an operation of generating or processing the IF signal S_IF in the sleep mode. In some embodiments, power supplied to at least some of the elements included in the RF module 30 may be blocked in the sleep mode. Blocking power may involve reducing, disconnecting, shutting off, switching off, or otherwise reducing or eliminating power to some or all elements included in the RF module 30. For example, power supplied to the switch SW, the low noise amplifier LNA, the RX phase shifter RX_PS, the TX phase shifter TX_PS, the power amplifier PA, and the temperature sensor TS that are included in the front-end RF circuit 33_1 may be blocked in the sleep mode and the power supplied to the temperature sensor TS may be maintained in the sleep mode. In addition, in some embodiments, power supplied to the LO generator 32 may be blocked in the sleep mode. Therefore, the temperature of the RF module 30 may be reduced in the sleep mode. The controller 16_1 may determine whether the temperature of the RF module 30 is reduced based on a time for which the RF module 30 is in the sleep mode and/or the temperature sensed by the temperature sensor TS in the sleep mode. When basing the determination on the time for which the RF module 30 is in the sleep mode, the controller 16_1 may refer to a set of predetermined information correlating reduction in temperature with times that power is blocked to one or more combinations of elements in the RF module 30. Sets of such predetermined information may be identified in advance based on testing, for example.

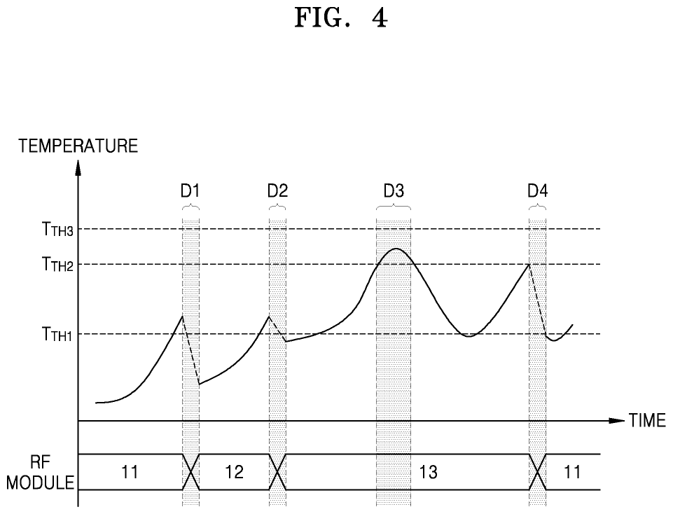

FIG. 4 is a graph illustrating an example of switching RF modules, according to an exemplary embodiment of the present disclosure. In detail, FIG. 4 illustrates representations of RF modules used for the wireless communication and a temperature of the RF modules over time. Hereinafter, FIG. 4 will be described with reference to FIG. 1.

The controller 16_1 of FIG. 1 may control the first RF module 11 to the fourth RF module 14 based on at least one reference temperature about the temperature of the RF module. For example, as illustrated in FIG. 4, the controller 16_1 may control the first RF module to the fourth RF module 14 based on a first temperature threshold value TTH1, a second temperature threshold value TTH2, and a third temperature threshold value TTH3 that are previously defined.

In some embodiments, when the temperature of the RF module exceeds the first temperature threshold value TTH1, the controller 16_1 may try to switch the RF module so that an RF module at a low temperature may perform the wireless communication. For example, as illustrated in FIG. 4, when the temperature of the first RF module 11 that performs the wireless communication exceeds the first temperature threshold value TTH1, the controller 16_1 may switch the RF module in a first period D1 and the second RF module 12 at a low temperature may perform the wireless communication. In other words, the controller 16_1 switches the wireless communication from the first RF module 11 to the second RF module 12. Subsequently, as shown, when the temperature of the second RF module 12 that performs the wireless communication exceeds the first temperature threshold value TTH1, the controller 16_1 may switch the RF module in a second period D2 and the third RF module 13 at a low temperature may perform the wireless communication. As shown, the first period D1, the second period D2, the third period D3 and the fourth period D4 are discontinuous. Additionally, as explained these periods are not predetermined insofar as the temperature of module exceeding a threshold may not be known in advance.

In some embodiments, when the temperature of the RF module being used in the wireless communication (e.g., the third RF module 13 in this example in FIG. 4) exceeds the second temperature threshold value TTH2, the controller 16_1 may limit an operation of the RF module (the third RF module 13 in this example in FIG. 4) in order to rapidly reduce the temperature of the RF module being used in the wireless communication. For example, as illustrated in FIG. 4, after the second period D2, the third RF module 13 may perform the wireless communication and a temperature of the third RF module 13 may increase. When all the first RF module 11, the second RF module 12, and the fourth RF module 14 excluding the third RF module 13 have temperatures of higher than or equal to the first temperature threshold value TTH1, switching RF modules in which one of the first RF module 11, the second RF module 12, and the fourth RF module 14 performs the wireless communication may not be performed and the temperature of the third RF module 13 may increase to the second temperature threshold value TTH2. When the temperature of the third RF module 13 exceeds the second temperature threshold value TTH2, the controller 16_1 may limit transmission power of the third RF module 13 or may set the third RF module 13 to be in the sleep mode. Therefore, after a third period D3, the temperature of the third RF module 13 may be reduced to lower than the second temperature threshold value TTH2.

In some embodiments, when the third RF module 13 is set to be in the sleep mode and the first RF module 11, the second RF module 12, and the fourth RF module 14 do not perform the wireless communication, access to the first wireless communication system (for example, 5G) using a relatively high frequency band may be cut. In this case, the UE 10 may access the second wireless communication system (for example, LTE) using a relatively low frequency band through an RF module different from the first RF module 11 to the fourth RF module 14. For example, a frequency band used for wireless communications may be lowered when the temperature of the first RF module 11 exceeds a threshold value or when a period in which the temperature of the first RF module 11 is higher than the threshold value exceeds a predefined period. Additionally, in a modification of these embodiments, some of the first RF module 11 to the fourth RF module 14 may be configured for use in accessing the first wireless communication (for example, 5G), and the remaining (i.e., the others) of the first RF module 11 to the fourth RF module 14 may be configured for use in accessing the second wireless communication (for example, LTE).

As illustrated in FIG. 4, when the temperature of the third RF module 13 is reduced to lower than the first temperature threshold value TTH1, the controller 16_1 may release the limiting (i.e., may reverse the limiting) of transmission power or may set the third RF module 13 to be in a normal mode. Therefore, the temperature of the third RF module 13 may rise again. When the temperature of the first RF module 11 set to be in the sleep mode is reduced to lower than the first temperature threshold value TTH1 in the first period D1, the controller 16_1 may switch RF modules in a fourth period D4 and the first RF module 11 at a low temperature may perform the wireless communication.

The third temperature threshold value TTH3 may correspond to the highest temperature among the first temperature threshold value TTH1 to the third temperature threshold value TTH3 as illustrated in FIG. 4 and may be a temperature at which a normal operation of the RF module is not guaranteed. Before the temperature of the RF module reaches the third temperature threshold value TTH3, for example, when the temperature of the RF module is higher than the second temperature threshold value TTH2, the controller 16_1 may perform an operation of reducing the temperature of the corresponding RF module as described above. Examples of the operation of the controller 16_1 of switching the RF module based on the temperature of the RF module are described above. However, in some embodiments, the controller 16_1 may switch the RF module based on quality of the wireless communication provided by the RF module as well as the temperature of the RF module as described later with reference to FIG. 5.

FIG. 5 is a flowchart illustrating another method of guaranteeing stability and performance of wireless communication, according to an exemplary embodiment of the present disclosure. The guarantee of stability and performance described herein is not necessarily a complete guarantee, and instead may be an attempt to guarantee stability and performance with the teachings described herein. Thus, the guarantee of stability and performance may also be characterized as an enhancement or attempted enhancement of stability and performance, and/or maintenance or attempted maintenance of stability and performance, for example. In detail, the flowchart of FIG. 5 illustrates examples of operation OP20 and operation OP40 of FIG. 2. As described above with reference to FIG. 2, in operation OP20′ of FIG. 5, it may be determined whether an RF module is to be switched and, in operation OP40′, the operation of selecting an RF module may be performed. Hereinafter, FIG. 5 will be described with reference to FIG. 1 assuming that the first RF module 11 of FIG. 1 currently performs the wireless communication.

Referring to FIG. 5, operation OP20′ may include multiple operations OP22, OP24, OP26, and OP28. In operation OP22, an operation of obtaining a temperature T1 of the first RF module 11 may be performed. For example, the controller 16_1 may receive a signal including information on the temperature sensed by a temperature sensor included in the first RF module 11 from the first RF module 11.

In operation OP24, an operation of comparing the temperature T1 of the first RF module 11 with the first temperature threshold value TTH1 may be performed. For example, as described above with reference to FIG. 4, the controller 16_1 may refer to the first temperature threshold value TTH1, the second temperature threshold value TTH2 and/or the third temperature threshold value TTH3 that are previously defined. The controller 16_1 may compare the temperature T1 of the first RF module 11 with the first temperature threshold value TTH1. As illustrated in FIG. 5, when the temperature T1 of the first RF module 11 is higher than the first temperature threshold value TTH1 (OP24=Yes), operation OP20′ may be terminated and operation OP40′ may be subsequently performed. That is, when the temperature T1 of the first RF module 11 is higher than the first temperature threshold value TTH1, regardless of the quality of the wireless communication performed by the first RF module 11, it may be determined that the first RF module 11 is to be switched. On the other hand, when the temperature T1 of the first RF module 11 is lower than or equal to the first temperature threshold value TTH1 (OP24=No), operation OP26 may be subsequently performed.

In operation OP26, an operation of evaluating quality Q1 of the wireless communication provided by the first RF module 11 may be performed. For example, when the temperature T1 of the first RF module 11 is lower than or equal to the first temperature threshold value TTH1, that is, when overheating of the first RF module 11 does not occur, the controller 16_1 may evaluate the quality Q1 of the wireless communication performed by the first RF module 11 in order to improve the quality of the wireless communication. The quality Q1 of the wireless communication performed by the first RF module 11 may be evaluated by various methods. In some embodiments, the controller 16_1 may evaluate the quality Q1 of the wireless communication performed by the first RF module 11 based on at least one of received power of a received signal, which is measured as a measured value by the first RF module 11. Received power of a received signal may be referred to as received power in the first RF module 11. The controller 16_1 may also evaluate the quality Q1 of the wireless communication based on power of the first IF signal S_IF1 and/or the baseband signal S_BB, which is measured as a measured value by the back-end module 15. The power of the first IF signal S_IF1 and/or the baseband signal S_BB may be referred to as received power in the back-end module 15. The controller 16_1 may alternatively evaluate the quality Q1 of the wireless communication based on various metrics of the baseband signal S_BB, which are measured as measured values by the data processor 16. Examples of metrics of the baseband signal S_BB that may be used for evaluating the quality Q1 of the wireless communication include a reference signal received power (RSRP), a received signal strength indicator (RSSI), reference signal received quality (RSRQ), and a signal to interference noise ratio (SINR). For example, the controller 16_1 may derive the quality Q1 of the wireless communication provided by the first RF module 11 by a function of at least one of the above-described various factors.

As described above, the controller 16_1 may be configured to switch RF modules based on power components of signals received by the RF modules. The controller 16_1 may also be configured to switch RF modules based on power of the baseband signal S_BB. As described above, the quality of the wireless communication may be based on at least one of received power in the first RF module 11, received power in the back-end module 15 which is used for receiving a down-converted signal from the first RF module 11, a reference signal received power, a received signal strength indicator, a reference signal received quality, or a signal to interference noise ratio of the wireless communication.

In operation OP28, an operation of comparing the quality Q1 of the wireless communication provided by the first RF module 11 with a quality threshold value QTH may be performed. For example, when the quality Q1 of the wireless communication performed by the first RF module 11 is no more than the previously defined quality threshold value QTH, the controller 16_1 may determine that the quality of the wireless communication performed by the first RF module 11 is not good. Therefore, as illustrated in FIG. 5, when the quality Q1 of the wireless communication performed by the first RF module 11 is no more than the quality threshold value QTH (OP28=No), operation OP20′ may be terminated and operation OP40′ may be subsequently performed. That is, when the quality Q1 of the wireless communication performed by the first RF module 11 is not good, it may be determined that the RF module is to be switched. On the other hand, when the quality Q1 of the wireless communication performed by the first RF module 11 is higher than the quality threshold value QTH (OP28=Yes), operation OP22 may be performed again.

In operation OP40′, based on the temperatures of the RF modules and/or the qualities of the wireless communication respectively provided by the RF modules, an operation of selecting an RF module may be performed. For example, the controller 16_1 may select the RF module to be switched based on the qualities of the wireless communication respectively provided by the first RF module 11 to the fourth RF module 14 as well as the temperatures of the first RF module 11 to the fourth RF module 14. As described above with reference to FIG. 2, the selected RF module may be the first RF module 11 that currently performs the wireless communication or another RF module, that is, one of the second RF module 12 to the fourth RF module 14. For example, when the quality of the wireless communication performed by the second RF module 12 is the same as the quality of the wireless communication performed by the third RF module 13 and the temperature of the second RF module 12 is lower than the temperature of the third RF module 13, the controller 16_1 may select the second RF module 12. On the other hand, when the quality of the wireless communication performed by the second RF module 12 is higher than the quality of the wireless communication performed by the third RF module 13 and the temperature of the second RF module 12 is higher than the temperature of the third RF module 13, the controller 16_1 may select the second RF module 12 or the third RF module 13 in accordance with whether the temperature of the second RF module 12 is lower than or equal to the first temperature threshold value TTH1. That is, though the temperature of the second RF module 12 is higher than the temperature of the third RF module 13, the second RF module 12 may be selected when the temperature of the second RF module 12 is still below the first temperature threshold value TTH1 since the quality of the wireless communication performed by the second RF module is higher. As a result, the RF module may be switched based on the quality of the wireless communication as well as the temperature of the RF module. Accordingly, both of performance and stability of the wireless communication may be obtained and used as the basis for selecting a RF module to use for wireless communication.

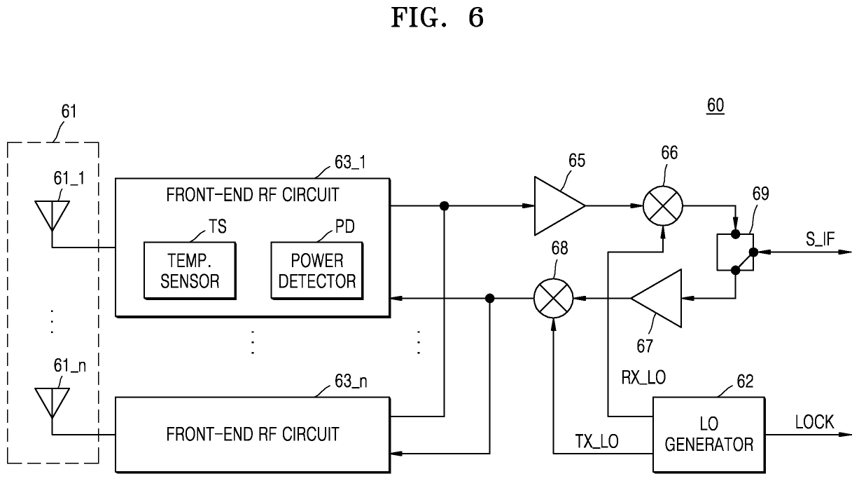

FIG. 6 is a block diagram illustrating another example of an RF module 60, according to an exemplary embodiment of the present disclosure. FIG. 7 is a block diagram illustrating an example of a back-end module 70, according to an exemplary embodiment of the present disclosure. In detail, the block diagrams of FIGS. 6 and 7 respectively illustrate examples of the RF module and the back-end module for measuring received power. FIGS. 6 and 7 will be described with reference to FIGS. 1 and 3. In FIG. 6, the description of the RF module previously given with reference to FIG. 3 is omitted.

Referring to FIG. 6, the RF module 60 may include an antenna array 61, an LO generator 62, multiple front-end RF circuits 63_1 to 63_n, buffers 65 and 67, mixers 66 and 68, and a switch 69 (n is an integer greater than 1). The antenna array 61 may include multiple antennas 61_1 to 61_n and the front-end RF circuits 63_1 to 63_n may respectively correspond to the antennas 61_1 to 61_n. Each of the front-end RF circuits 63_1 to 63_n may include a power detector as well as a temperature sensor. For example, as illustrated in FIG. 6, the front-end RF circuit 63_1 may include a temperature sensor TS and a power detector PD. As described above with reference to FIG. 3, the temperature sensor TS may sense a temperature of the front-end RF circuit 63_1.

The power detector PD may detect power of a signal received through the antenna 61_1 and/or a signal obtained by processing the corresponding signal received through the antenna 61_1. For example, the power detector PD may detect power of a signal from an input or output of a low noise amplifier (for example, the LNA of FIG. 3) included in the front-end RF circuit 63_1 and/or an output of an RX phase shifter (for example, the RX_PS of FIG. 3). The power detector PD may generate a signal including information on the detected power and may provide the generated signal to the controller 16_1. In some embodiments, the RF module 60 may further include an element for collecting signals provided by power detectors of the front-end RF circuit 63_1 to front-end RF circuit 63_n and providing a signal including power information (for example, an average of power components and a maximum value) to the controller 16_1 based on the collected signals.

Referring to FIG. 7, the back-end module 70 may include a first port pair P10 to a fourth port pair P40 for accessing the first RF module 11 to the fourth RF module 14. Two ports included in a port pair may be connected to the same RF module or may be respectively connected to different RF modules. In addition, the back-end module 70 may include four circuit groups corresponding to the first port pair P10 to the fourth port pair P40. For example, as illustrated in FIG. 7, the back-end module 70 may include a first switch SW1 to a fourth switch SW4 respectively connected to the first port pair P10 to the fourth port pair P40 and circuits for processing a signal between the first switch SW1 to the fourth switch SW4 and a data processor 80. For example, the baseband signal S_BB received from a digital-to-analog converter (DAC) 86 of the data processor 80 may be processed by a TX filter 71, a TX mixer 72, and an amplifier 73 and an output signal of the amplifier 73 may be provided to the first switch SW1. In some embodiments, the amplifier 73 may include a variable gain amplifier. In addition, the signal received from the first switch SW1 may be processed by an RX mixer 74 and an RX filter 75 and an output signal of the RX filter 75 may be provided to an analog-to-digital converter 82 (ADC) of the data processor 80.

As illustrated in FIG. 7, the back-end module 70 may include a PLL 76 and a power detector 77. The PLL 76 may provide local oscillation signals to mixers included in the back-end module 70. In some embodiments, as described above with reference to FIG. 1, when the mixers are omitted from the back-end module 70, the PLL 76 may also be omitted. The power detector 77 may detect power of a signal received from the back-end module 70 and/or a signal obtained by processing the received signal. For example, when a signal is received through the first port pair P10, the power detector 77 may detect power of the signal from an input of the RX mixer 74, an input of the RX filter 75, and/or an output of the RX filter 75. The power detector 77 may provide a signal including information on the detected power to a controller 89.

The data processor 80 may include ADCs 81 to 84 (analog to digital converters), DACs 85 to 88 (digital to analog converters), and the controller 89. Each of the multiple ADCs 81 to 84 may receive the baseband signal S_BB from the back-end module 70 and may convert the baseband signal S_BB into a digital signal. Each of the multiple DACs 85 to 88 may generate the baseband signal S_BB by converting the digital signal and may provide the baseband signal S_BB to the back-end module 70. The controller 89 may evaluate the quality of the wireless communication performed by the RF module that currently performs the wireless communication based on metrics measured from received power information provided by the power detector 77 and/or digital signals output by the multiple DACs 85 to 88.

FIG. 8 is a flowchart illustrating another method of guaranteeing stability and performance of wireless communication, according to an exemplary embodiment of the present disclosure. In detail, the flowchart of FIG. 8 illustrates an example of operation OP60 of FIG. 2. As described above with reference to FIG. 2, so that the wireless communication is performed in operation OP60′ of FIG. 8, an operation of controlling the selected RF module may be performed. Hereinafter, FIG. 8 will be described with reference to FIGS. 1 and 3 assuming that the first RF module 11 of FIG. 1 currently performs the wireless communication.

Referring to FIG. 8, operation OP60′ may include multiple operations OP61, OP63, OP65, OP67, and OP69. In operation OP61, an operation of determining whether the first RF module 11 is the same as the selected RF module may be performed. For example, when the RF module selected in operation OP40 of FIG. 2 is the same as the first RF module 11 that currently performs the wireless communication (OP61=Yes), as illustrated in FIG. 8, the controller 16_1 may not perform operations for switching RF modules, for example, operations OP63, OP65, OP67, and OP69 and the first RF module 11 may continuously perform the wireless communication. On the other hand, when the RF module selected in operation OP40 of FIG. 2 is different from the first RF module 11 that currently performs the wireless communication (OP61=No), operation OP63 may be subsequently performed.

In operation OP63, an operation of storing information on (e.g., about, regarding) the first RF module RF11 may be performed. For example, the controller 16_1 may store the information on the first RF module RF11 in a context storage CS. The information on the first RF module RF11 may be information on the wireless communication performed by the first RF module RF11 and include, for example, the quality of the wireless communication, beamforming set coefficients, and amplification gain information. In order to store the information on the RF module, the context storage CS may include volatile memory such as static random access memory (SRAM) or dynamic random access memory (DRAM) or non-volatile memory such as flash memory or electrically erasable programmable read only memory (EEPROM). The context storage CS may be included in the controller 16_1, or the controller 16_1 may access the context storage CS outside the data processor 16.

In operation OP65, an operation of setting the first RF module 11 to be in the sleep mode may be performed. For example, the controller 16_1 may set the first RF module 11 to be changed from the normal mode to the sleep mode. As described above with reference to FIG. 3, in the sleep mode, the first RF module 11 may not perform the wireless communication and power supplied to at least one element included in the first RF module 11 may be blocked. Therefore, the temperature of the first RF module 11 may start to be reduced. In some embodiments, unlike in FIG. 8, operation OP63 may be performed subsequent to operation OP65 and/or operations OP63 and OP65 may be performed in parallel.

In operation OP67, an operation of obtaining previous information on the selected RF module may be performed. For example, the controller 16_1 may obtain the previous information on the selected RF module from the context storage CS. When the selected RF module performs the wireless communication before the first RF module 11 performs the wireless communication, as the information on the first RF module 11 is stored in the context storage CS in operation OP63, the context storage CS may store information on the selected RF module. As described above, the information on the selected RF module may include the quality of the wireless communication, the beamforming set coefficients, and the amplification gain information. When a difference between an environment of the wireless communication performed by the selected RF module and an environment of the current wireless communication is not significant, the selected RF module may start to perform the wireless communication at an early stage by using the information obtained from the context storage CS.

In operation OP69, an operation of controlling the selected RF module may be performed. For example, the controller 16_1 may set a path so that a signal processed by the selected RF module is processed by the back-end module 15. The controller 16_1 may set a path so that a signal generated by the back-end module 15 is processed by the selected RF module by controlling the switches. In addition, the controller 16_1 may set the selected RF module based on the information obtained in operation OP67.

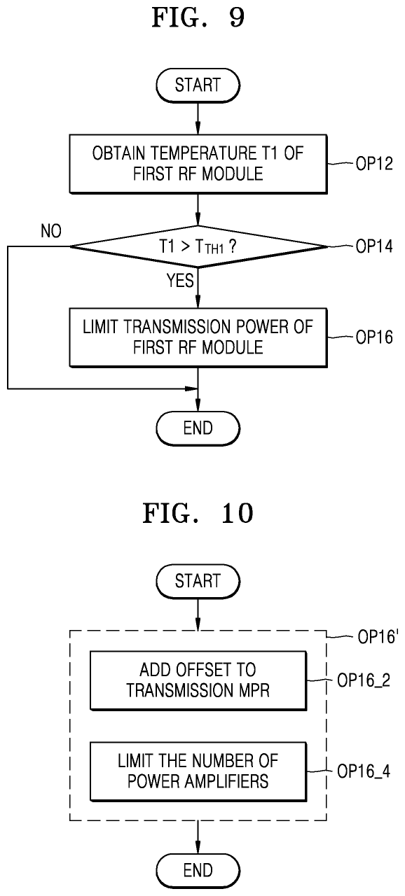

FIG. 9 is a flowchart illustrating another method of guaranteeing stability and performance of wireless communication, according to an exemplary embodiment of the present disclosure. In detail, the flowchart of FIG. 9 illustrates a method of limiting an operation of an RF module in accordance with a temperature of the RF module. In some embodiments, the method of FIG. 9 may be performed by the controller 16_1 of FIG. 1. Hereinafter, FIG. 9 will be described with reference to FIG. 1 assuming that the first RF module 11 of FIG. 1 currently performs the wireless communication.

In operation OP12, an operation of obtaining the temperature T1 of the first RF module 11 may be performed. Next, in operation OP14, an operation of comparing the temperature T1 of the first RF module 11 with the first temperature threshold value TTH1 may be performed. As described above with reference to FIGS. 4 and 5, when the temperature T1 of the first RF module 11 is lower than or equal to the first temperature threshold value TTH1 (OP14=No), heat emission of the first RF module 11 may not matter. For example, heat emission may not be expected to impact the performance of the first RF module 11 when the temperature T1 of the first RF module 11 is lower than or equal to the first temperature threshold value TTH1. Therefore, as illustrated in FIG. 9, the method of FIG. 9 may be terminated. On the other hand, when the temperature T1 of the first RF module 11 is higher than the first temperature threshold value TTH1 (OP14=Yes), it may be required to control the heat emission of the first RF module 11 and, as illustrated in FIG. 9, operation OP16 may be subsequently performed.

In operation OP16, an operation of limiting transmission power of the first RF module 11 may be performed. As described above with reference to FIG. 5, when the temperature T1 of the first RF module 11 is higher than the first temperature threshold value TTH1, a switching of the first RF module 11 may be tried. However, in accordance with temperatures of other RF modules and/or qualities of wireless communications performed by the other RF modules, it may be determined that the first RF module 11 is to continuously perform the wireless communication. Therefore, in order to prevent the temperature T1 of the first RF module 11 from rising (for example, to higher than or equal to the second temperature threshold value TTH2), the controller 16_1 may limit the transmission power of the first RF module 11. The heat emission of the RF module may be mainly caused by the power amplifier(s) included in the RF module. Therefore, an increase rate of the temperature T1 of the first RF module 11 may be reduced or the temperature T1 of the first RF module 11 may be reduced by limiting the transmission power of the first RF module 11. Limiting the transmission power of the first RF module 11 may be accomplished by reducing the usage of one or more power amplifier and/or by limiting power supplied to the first RF module 11 or selected individual elements of the first RF moduli 11. An example of operation OP16 will be described later with reference to FIG. 10.

FIG. 10 is a flowchart illustrating another method of guaranteeing stability and performance of wireless communication, according to an exemplary embodiment of the present disclosure. In detail, the flowchart of FIG. 10 illustrates an example of operation OP16 of FIG. 9. As described above with reference to FIG. 9, in operation OP16′ of FIG. 10, an operation of limiting the transmission power of the first RF module 11 may be performed. In FIG. 10, it is illustrated that operation OP16′ includes operations OP16_2 and OP16_4. However, in some embodiments, operation OP16′ may include only one of operations OP_2 and OP_4. In some embodiments, operation OP16′ of FIG. 10 may be performed by the controller 16_1 of FIG. 1. Hereinafter, FIG. 10 will be described with reference to FIG. 1.

In operation OP16_2, an operation of adding an offset to transmission maximum power reduction (MPR) may be performed. The offset to transmission MPR may be referred to as an MPR offset. The wireless communication system may regulate the transmission MPR as an allowable reduction of the maximum transmission power in accordance with a condition considering realistic performance of a communication device. For example, the wireless communication system may vary regulation of the transmission MPR in accordance with a channel bandwidth and a modulation order. The transmission MPR may therefore be or reflect a limit or adjusted limit on transmission power allowed for the communication device and may vary based on conditions. The controller 16_1 may add an offset for limiting the transmission power of the first RF module 11 to the transmission MPR determined in accordance with the condition of the wireless communication, for example, the channel bandwidth and the modulation order. Therefore, the transmission power of the first RF module 11 may be reduced by the transmission MPR and the added offset.

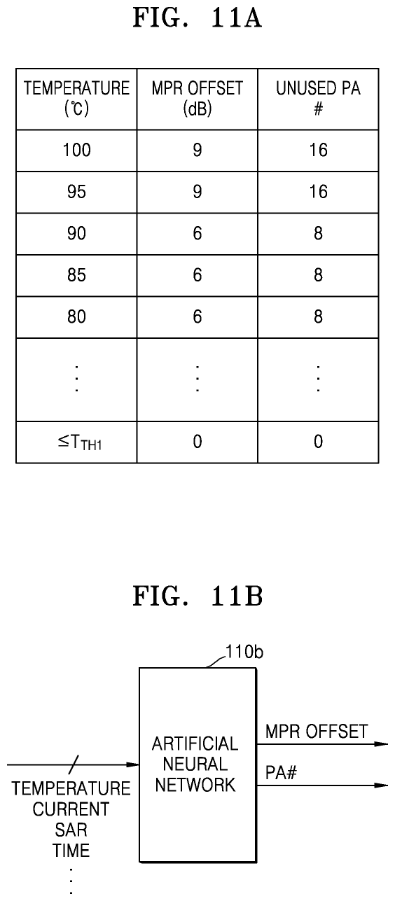

In operation OP16_4, an operation of limiting the number of power amplifiers may be performed. As described above with reference to FIG. 3, the RF module may include the antenna array including the antennas and may include power amplifiers respectively corresponding to the antennas. Since power consumed by the power amplifiers is significant, the controller 16_1 may limit the transmission power by limiting the number of power amplifiers used for the wireless communication among the power amplifiers included in the first RF module 11. Examples of the offset in operation OP16_2 and determining the number of power amplifiers in operation OP16_4 will be described later with reference to FIGS. 11A and 11B.

FIG. 11A illustrates a table used in an operation of limiting transmission power of an RF module, according to exemplary embodiments of the present disclosure. FIG. 11B illustrates an operation of an artificial neural network in limiting transmission power of an RF module, according to exemplary embodiments of the present disclosure. In detail, FIG. 11A illustrates a lookup table 110a that may be used for limiting the transmission power of the RF module and FIG. 11B illustrates an ANN 110b (artificial neural network) that may be used for limiting the transmission power of the RF module. The lookup table 110a may include information on transmission power components corresponding to combinations of characteristics of the RF module. The transmission MPR offset and the number of power amplifiers may be drawn from the lookup table 110a of FIG. 11A and the ANN 110b of FIG. 11B. However, it will be understood that, in some embodiments, a lookup table and an ANN that provide only one of the MPR offset and the number of power amplifiers may be used. Hereinafter, FIGS. 11A and 11B will be described with reference to FIG. 1. The ANN 110b may be trained to output transmission power.

Referring to FIG. 11A, the controller 16_1 may obtain the MPR offset and the number of power amplifiers with reference to the lookup table 110a. For example, as illustrated in FIG. 11A, the lookup table 110a may include information on transmission power components corresponding to one or multiple combinations including a temperature, an MPR offset, and the number of unused power amplifiers. For example, when the temperature of the RF module is 90° C., the controller 16_1 may add 6 dB as the MPR offset and may perform control so that eight power amplifiers are not used. In addition, when the temperature of the RF module is no more than the first temperature threshold value TTH1, the controller 16_1 may not add the MPR offset and all the power amplifiers included in the RF module may be used. Although not shown in FIG. 11A, the lookup table 110a may further include at least one column corresponding to a current consumed by the RF module, a specific absorption rate (SAR) of the RF module and maximum permissible exposure (MPE) that is caused by the RF module, and/or a driving time for which the wireless communication is continuously performed by the RF module as well as the temperature as a factor for determining the MPR offset and the number of power amplifiers. The lookup table 110a may be stored in the non-volatile memory such as the flash memory or the EEPROM. The lookup table 110a may be included in the controller 16_1 or the controller 16_1 may access the lookup table 110a outside the data processor 16.

Referring to FIG. 11B, the controller 16_1 may obtain the MPR offset and the number of power amplifiers from the ANN 110b. For example, as illustrated in FIG. 11B, the ANN 110b may receive at least one of the temperature, the current consumed by the RF module, the specific absorption rate (SAR) caused by the RF module, or the driving time for which the wireless communication is continuously performed by the RF module and may output the MPR offset and the number of power amplifiers in response to received inputs. The ANN 110b may refer to a structure of implementing sets in which artificial neurons (or neuron models) are connected to each other. An artificial neuron may generate output data by performing simple operations on input data and may transmit the output data to another artificial neuron. The ANN 110b may be a state trained by the combinations of the above-described temperature, current, specific absorption rate (SAR), and driving time and may output the MPR offset and the number of power amplifiers in response to the inputs provided by the controller. The ANN 110b may be trained to output transmission power based on at least one of temperature, power consumption, and driving time of the RF module and a specific absorption rate (SAR) of the RF module.

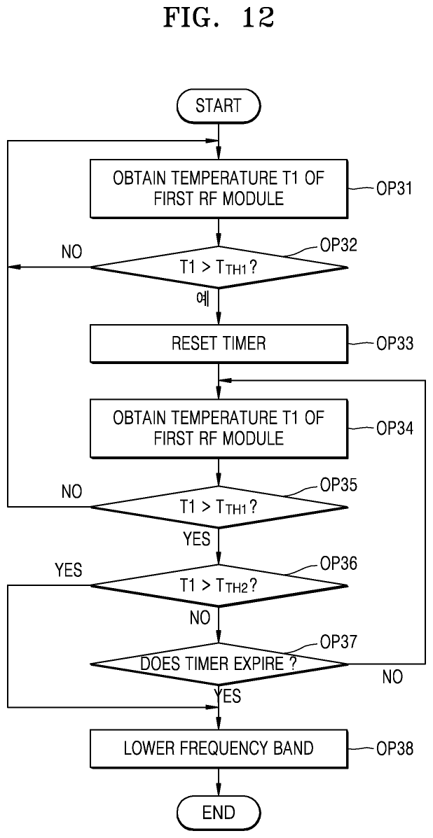

FIG. 12 is a flowchart illustrating another method of guaranteeing stability and performance of wireless communication, according to an exemplary embodiment of the present disclosure. In detail, the flowchart of FIG. 12 illustrates an operation of lowering a frequency band used for the wireless communication in order to control the temperature of the RF module. In some embodiments, the method of FIG. 12 may be performed by the controller 16_1 of FIG. 1. Hereinafter, FIG. 12 will be described with reference to FIG. 1 assuming that the first RF module 11 of FIG. 1 currently performs the wireless communication.

In operation OP31, an operation of obtaining the temperature T1 of the first RF module 11 may be performed. In operation OP32, an operation of comparing the temperature T1 of the first RF module 11 with the first temperature threshold value TTH1 may be performed. As illustrated in FIG. 12, when the temperature T1 of the first RF module 11 is lower than or equal to the first temperature threshold value TTH1 (OP32=No), operation OP31 may be performed again. When the temperature T1 of the first RF module 11 is higher than the first temperature threshold value TTH1 (OP32=Yes), operation OP33 may be subsequently performed.

In operation OP33, an operation of resetting a timer may be performed. For example, the controller 16_1 may reset the timer in order to measure a driving time for which the temperature T1 of the first RF module 11 is maintained to be higher than the first temperature threshold value TTH1. As described later, the timer may be used for measuring a driving time for which the temperature T1 of the first RF module 11 is maintained between the first temperature threshold value TTH1 and the second temperature threshold value TTH2.

In operation OP34, an operation of obtaining the temperature T1 of the first RF module 11 may be performed. In operation OP35, an operation of comparing the temperature T1 of the first RF module 11 with the first temperature threshold value TTH1 may be performed. As illustrated in FIG. 12, when the temperature T1 of the first RF module 11 is lower than or equal to the first temperature threshold value TTH1 (OP35=No), operation OP31 may be performed. When the temperature T1 of the first RF module 11 is higher than the first temperature threshold value TTH1 (OP35=Yes), operation OP36 may be subsequently performed.

In operation OP36, an operation of comparing the temperature T1 of the first RF module 11 with the second temperature threshold value TTH2 may be performed. As described above with reference to FIG. 4, when the temperature T1 of the first RF module 11 is higher than the second temperature threshold value TTH2 (OP36=Yes), an operation of reducing the temperature T1 of the first RF module 11 may be required. Therefore, as illustrated in FIG. 12, when the temperature T1 of the first RF module 11 is higher than the second temperature threshold value TTH2 (OP36=Yes), operation OP38 may be subsequently performed. On the other hand, when the temperature T1 of the first RF module 11 is lower than or equal to the second temperature threshold value TTH2 (OP36=No), that is, when the temperature T1 of the first RF module 11 is maintained between the first temperature threshold value TTH1 and the second temperature threshold value TTH2, operation OP37 may be subsequently performed.

In operation OP37, an operation of determining whether the timer expires may be performed. For example, the timer may expire when a previously defined time is exceeded. When the timer expires (OP37=Yes), the controller 16_1 may determine that the time for which the temperature T1 of the first RF module 11 is maintained between the first temperature threshold value TTH1 and the second temperature threshold value TTH2 exceeds the predefined time. When the timer expires (OP37=Yes), the controller 16_1 may subsequently perform the operation of reducing the temperature T1 of the first RF module 11 in order to prevent the first RF module 11 from being damaged and/or to protect a user who is using the UE 10. Therefore, as illustrated in FIG. 12, when the timer expires, operation OP38 may be subsequently performed. When the timer does not expire (OP37=No), operation OP34 may be performed again.

In operation OP38, the operation of lowering the frequency band used for the wireless communication may be performed. For example, when the first RF module 11 performs the wireless communication by using mmWave, the controller 16_1 may control the first RF module 11 to perform the wireless communication by using a frequency band lower than mmWave, for example, sub 6 GHz 5G. In some embodiments, the controller 16_1 may set the first RF module 11 to be in the sleep mode and may control another RF module in order to access the legacy wireless communication system, for example, the second wireless communication system using a low frequency band such as LTE. Accordingly, a frequency band used for wireless communications may be lowered for various reasons such as when the temperature of the first RF module 11 exceeds a threshold value or when a period in which the temperature of the first RF module 11 is higher than the threshold value exceeds a predefined period.

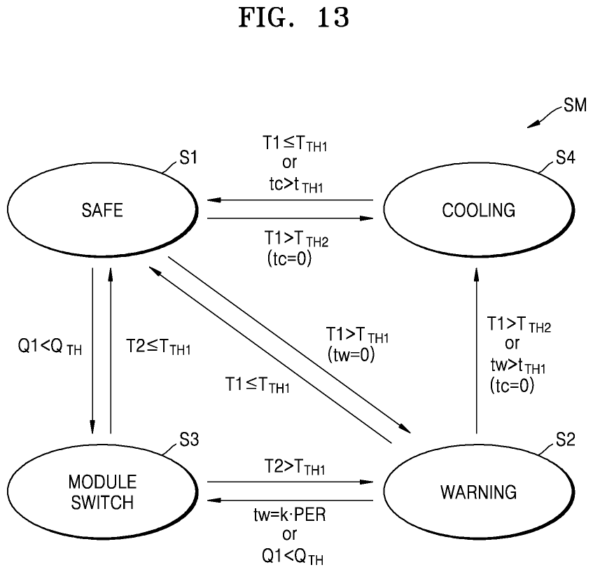

FIG. 13 illustrates a state machine SM for performing a method of guaranteeing stability and performance of wireless communication, according to an exemplary embodiment of the present disclosure. As illustrated in FIG. 13, the state machine SM may include four states S1, S2, S3, and S4 and state transition may occur among the four states S1, S2, S3, and S4 based on the temperatures of the RF modules and the qualities of the wireless communications respectively provided by the RF modules. In some embodiments, the state machine SM may be implemented by the controller 16_1 of FIG. 1. Hereinafter, FIG. 13 will be described with reference to FIG. 1 assuming that the first RF module 11 currently performs the wireless communication.

In a safe state S1 (that may be referred to as a first state), the first RF module 11 may perform the wireless communication without limitations on an operation, which are caused by the temperature T1. However, as illustrated in FIG. 13, when the temperature T1 of the first RF module 11 is higher than the first temperature threshold value TTH1 in the safe state S1 (T1>TTH1), transition to a warning state S2 may occur. During the transition from the safe state S1 to the warning state S2, “tw” that represents a time for which the warning state S2 is maintained may be reset (tw=0). In addition, when the quality Q1 of the wireless communication provided by the first RF module 11 is lower than the quality threshold value QTH in the safe state S1 (Q1<QTH), transition to a module switch state S3 may occur. In some embodiments, the transition from the safe state S1 to the module switch state S3 may periodically occur so that the first RF module 11 may be switched into an RF module by which the wireless communication with better quality may be performed. That is, in the safe state S1, the first RF module 11 is not switched only due to the temperature thereof and may also or instead be switched due to the quality of the wireless communication performed thereby. Additionally, the state machine SM may transit among some of the states (e.g., from the warning state S2) based on a period in which a transited state is maintained. In addition, when the temperature T1 of the first RF module 11 is higher than the second temperature threshold value TTH2 in the safe state S1 (T1>TTH2), transition to a cooling state S4 may occur. As illustrated in FIG. 13, during the transition from the safe state S1 to the cooling state S4, “tc” that represents a time for which the cooling state S4 is maintained may be reset (tc=0).

In the warning state S2 (that may be referred to as a second state), the temperature T1 of the first RF module 11 may be maintained between the first temperature threshold value TTH1 and the second temperature threshold value TTH2 and switching from the first RF module 11 may be attempted. In addition, in some embodiments, as described above with reference to FIG. 9, in the warning state S2, the transmission power of the first RF module 11 may be limited. For example, as illustrated in FIG. 13, transition from the warning state S2 to the module switch state S3 may occur every period PER (tw=k·PER, k is an integer greater than 0). When the quality Q1 of the wireless communication performed by the first RF module 11 is lower than the quality threshold value QTH (Q1<QTH), transition to the module switch state S3 may occur. In addition, when the temperature T1 of the first RF module 11 is less than or equal to the first temperature threshold value TTH1 (T1≤TTH1), transition to the safe state S1 may occur. In addition, when the temperature T1 of the first RF module 11 is higher than the second temperature threshold value TTH2 (T1>TTH2) or the time for which the warning state S2 is maintained exceeds a first time threshold value tTH1, the transition to the cooling state S4 may occur. As illustrated in FIG. 13, during the transition from the warning state S2 to the cooling state S4, “tc” that represents the time for which the cooling state S4 is maintained may be reset (tc=0).

In the module switch state S3 (that may be referred to as a third state), an operation of switching RF modules may be performed. For example, a proper RF module may be selected among the first RF module 11 to the fourth RF module 14 including the first RF module 11. When the second RF module 12 different from the first RF module 11 is selected, as described above with reference to FIG. 8, the information on the first RF module 11 may be stored and the first RF module 11 may be set to be in the sleep mode. In addition, information on the second RF module 12 may be obtained and, based on the obtained information, the second RF module 12 may be controlled to perform the wireless communication. As illustrated in FIG. 13, when a temperature T2 of the second RF module 12 is lower than or equal to the first temperature threshold value TTH1, transition from the module switch state S3 to the safe state S1 may occur. When the temperature T2 of the second RF module 12 is higher than the first temperature threshold value TTH1, transition from the module switch state S3 to the warning state S2 may occur.

In the cooling state S4 (that may be referred to as a fourth state), the operation of reducing the temperature T1 of the first RF module 11 may be performed. For example, as described above with reference to FIG. 12, the first RF module 11 may be set to be in the sleep mode and the operation of lowering the frequency band used for the wireless communication may be performed. Therefore, the temperature T1 of the first RF module 11 may be reduced. When the first RF module 11 is completely cooled, transition from the cooling state S4 to the safe state S1 may occur. For example, as illustrated in FIG. 13, when the temperature T1 of the first RF module 11 is lower than or equal to the first temperature threshold value TTH1 (T1≤TTH1) or the time for which the cooling state S4 is maintained exceeds a second time threshold value tTH2, transition to the safe state S1 may occur.

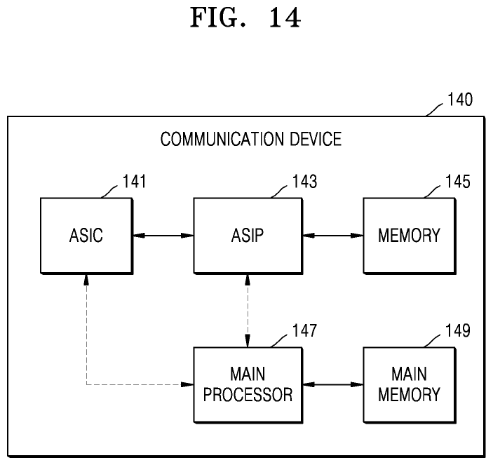

FIG. 14 is a block diagram illustrating an example of a communication device 140, according to an exemplary embodiment of the present disclosure. In some embodiments, the communication device 140 may be included in the UE 10 of FIG. 1 and may perform the operation of the controller 16_1.

As illustrated in FIG. 14, the communication device 140 may include an ASIC 141 (application specific integrated circuit), an ASIP 143 (application specific instruction set processor), memory 145, a main processor 147, and main memory 149. Two or more elements among the ASIC 141, the ASIP 143, and the main processor 147 may communicate with each other. In addition, two or more elements among the ASIC 141, the ASIP 143, the memory 145, the main processor 147, and the main memory 149 may be mounted in one chip.

The ASIP 143 as an integrated circuit customized for particular use may support an instruction set exclusive for a particular application and may execute an instruction included in an instruction set. The memory 145 may communicate with the ASIP 143 and may store multiple instructions executed by the ASIP 143 as a non-temporary storage device. As a non-restrictive example, the memory 145 may include arbitrary kind of memory accessible by the ASIP 143 such as random access memory (RAM), read only memory (ROM), a tape, a magnetic disk, an optical disk, volatile memory, non-volatile memory, or a combination of the above elements.

The main processor 147 may control the communication device 140 by executing the instructions. For example, the main processor 147 may control the ASIC 141 and the ASIP 143 and may process data received through the wireless communication network or a user input to the communication device 140. The main memory 149 may communicate with the main processor 147 and may store the instructions executed by the main processor 147 as the non-temporary storage device. As a non-restrictive example, the main memory 149 may include arbitrary kind of memory accessible by the main processor 147 such as the RAM, the ROM, the tape, the magnetic disk, the optical disk, the volatile memory, the non-volatile memory, or the combination of the above elements.

Some or all aspects of methods of guaranteeing the stability and performance of the wireless communication may be performed directly or indirectly by at least one of the elements included in the communication device 140 of FIG. 14. In some embodiments, the operation of the controller 16_1 of FIG. 1 may be implemented as multiple instructions stored in the memory 145 and the ASIP 143 may perform at least one of operations of the methods of guaranteeing the stability and performance of the wireless communication described herein by executing the instructions stored in the memory 145. In some embodiments, at least one of operations of the methods of guaranteeing the stability and performance of the wireless communication described herein may be performed by a hardware block designed through the logic synthesis and the hardware block may be included in the ASIC 141. In some embodiments, at least one of operations of a method of controlling exposure to the wireless communication may be implemented by multiple instructions stored in the main memory 149. The main processor 147 may perform at least one of operations of the methods of guaranteeing the stability and performance of the wireless communication described herein by executing the instructions stored in the main memory 149.

While the inventive concept(s) of the present disclosure have been particularly shown and described with reference to embodiments thereof, it will be understood that various changes in form and details may be made therein without departing from the spirit and scope of the following claims.

What is claimed is:

1. A wireless communication device, comprising:
a plurality of radio frequency (RF) modules each connected to at least one antenna and each including a temperature sensor;
a back-end module configured to generate a baseband signal from signals provided by the plurality of RF modules; and
a controller configured to switch RF modules based on temperatures of the plurality of RF modules so that a RF module performing wireless communication among the plurality of RF modules is changed from a first RF module to a second RF module.

2. The wireless communication device of claim 1,
wherein each of the plurality of RF modules comprises a power detector configured to detect received power of a signal received through the at least one antenna, and
wherein the controller is configured to switch the RF modules based on power components of signals received by the plurality of RF modules.

3. The wireless communication device of claim 1,
wherein the back-end module comprises a power detector configured to detect power of the baseband signal generated by the back-end module, and
wherein the controller is configured to switch the RF modules based on the power of the baseband signal.

4. The wireless communication device of claim 1,
wherein the controller is configured to measure as a measured value at least one of a reference signal received power (RSRP), a received signal strength indicator (RSSI), reference signal received quality (RSRQ), or a signal to interference noise ratio (SINR) of baseband signals respectively corresponding to the plurality of RF modules and to switch the RF modules based on the measured value.

5. The wireless communication device of claim 1,
wherein the controller is configured to limit transmission power of the first RF module based on at least one of a temperature of the first RF module, power consumption of the first RF module, a driving time of the first RF module, or a specific absorption rate (SAR) due to the first RF module.

6. The wireless communication device of claim 5,
wherein the controller comprises:
a lookup table including information on transmission power components corresponding to one or more combinations of the temperature of the first RF module, the power consumption of the first RF module, the driving time of the first RF module, and the specific absorption rate of the first RF module; or
an artificial neural network (ANN) trained to output transmission power from at least one of the temperature of the first RF module, the power consumption of the first RF module, the driving time of the first RF module, or the specific absorption rate due to the first RF module.

7. A method for guaranteeing stability and performance of wireless communication using a plurality of radio frequency (RF) modules, the method comprising:
determining whether to switch the RF modules based on a temperature of a first RF module performing the wireless communication among the plurality of RF modules;
selecting a second RF module among the plurality of RF modules based on temperatures of the plurality of RF modules based on determining to switch the RF modules; and
controlling the second RF module to perform the wireless communication.

8. The method of claim 7,
wherein the determining whether to switch the RF modules comprises determining that switching the RF modules is to be performed when the temperature of the first RF module exceeds a first threshold value.

9. The method of claim 8, further comprising:
limiting transmission power of the first RF module when the temperature of the first RF module exceeds the first threshold value.

10. The method of claim 9,
wherein the limiting of the transmission power of the first RF module comprises at least one of:
adding an offset to transmission maximum power reduction (MPR) based on the temperature of the first RF module; or
limiting a number of power amplifiers used by the first RF module based on the temperature of the first RF module.

11. The method of claim 8, further comprising:
lowering a frequency band used for the wireless communication when the temperature of the first RF module exceeds a second threshold value which is greater than the first threshold value or a period in which the temperature of the first RF module is higher than the first threshold value exceeds a predefined period.

12. The method of claim 11, further comprising:
making the frequency band used for the wireless communication higher based on at least one of a period in which the wireless communication is performed in a low frequency band or the temperature of the first RF module.

13. The method of claim 8,
wherein the determining whether to switch the RF modules comprises:
determining that switching of the RF modules is to be performed based on quality of the wireless communication when the temperature of the first RF module does not exceed the first threshold value.

14. The method of claim 13,
wherein the quality of the wireless communication comprises at least one of received power in the first RF module, received power in a back-end module that receives a down-converted signal from the first RF module, a reference signal received power (RSRP), a received signal strength indicator (RSSI), a reference signal received quality (RSRQ), or a signal to interference noise ratio (SINR) of the wireless communication.

15. The method of claim 7,
wherein the selecting of the second RF module comprises:
determining the second RF module based on temperatures of the plurality of RF modules and quality of the wireless communication provided by each of the plurality of RF modules.

16. The method of claim 7,
wherein the controlling of the second RF module comprises:
setting the first RF module to be in a sleep mode when the first RF module and the second RF module are different from each other.

17. The method of claim 7,
wherein the controlling of the second RF module comprises:
storing information on the first RF module used for the wireless communication when the first RF module and the second RF module are different from each other.

18. The method of claim 17,
wherein the controlling of the second RF module comprises:
obtaining the information on the second RF module used for the wireless communication and controlling the second RF module in accordance with the obtained information when the first RF module and the second RF module are different from each other.

19. A wireless communication device, comprising:
a plurality of radio frequency (RF) modules each connected to at least one antenna and each including a temperature sensor; and
a state machine configured to transit among a plurality of states based on temperatures of the plurality of RF modules and quality of wireless communication provided by each of the plurality of RF modules,
wherein the plurality of states comprise:
a first state in which a first RF module among the plurality of RF modules performs wireless communication at a temperature lower than or equal to a first threshold value;
a second state in which the first RF module performs the wireless communication at a temperature higher than the first threshold value;
a third state in which switching RF modules is performed so that a second RF module among the plurality of RF modules performs the wireless communication; and
a fourth state in which the plurality of RF modules are set to be in a sleep mode.

20. The wireless communication device of claim 19,
wherein the state machine is configured to transit among at least some of the plurality of states based on a period in which a transited state is maintained.
